(19) United States
(12) Patent Application Publication
(10) Pub. No.: US 2023/0344191 A1
(43) Pub. Date: Oct. 26, 2023

(54) TUNABLE TRANSMISSION-GRATING LASER WITH FEEDBACK

(71) Applicant: Intuitive Surgical Operations, Inc., Sunnyvale, CA (US)

(72) Inventors: Mark E. Froggatt, Blacksburg, VA (US); Brooks Childers, Christiansburg, VA (US); Kevin M. Marsden, Blachsburg, VA (US); Eric E. Sanborn, Blacksburg, VA (US)

(21) Appl. No.: 18/008,112

(22) PCT Filed: Jun. 2, 2021
(86) PCT No.: PCT/US2021/035547

§ 371 Date: Dec. 2, 2022

Related U.S. Application Data
(60) Provisional application No. 63/034,268, filed on Jun. 3, 2020.

(51) Int. Cl. H01S 3/137; H01S 3/13; H01S 3/139; H01S 3/08

(52) U.S. Cl. CPC H01S 3/137; H01S 3/1305; H01S 3/139; H01S 3/08009

(57) ABSTRACT

In a tunable transmission-grating laser, alignment of the lasing cavity mode with the grating filter spectrum of the laser can be achieved using the position of the intracavity beam relative to the gain medium as feedback. In various embodiments, the displacements of the intracavity beam from the gain medium are monitored indirectly, using an image of the intracavity beam created outside the cavity with an additional transmission grating. Various means for measuring the position of that monitoring beam and for adjusting the tunable components of the laser based thereon are described.

### CROSS-REFERENCE TO RELATED APPLICATION

This application claims priority to, and the benefit of, U.S. Provisional Patent Application No. 63/034,268, filed on Jun. 3, 2020, which is hereby incorporated herein by reference in its entirety.

### BACKGROUND

Many optical sensing and imaging techniques, including, for instance, Optical Frequency Domain Reflectometry (OFDR), gas absorption line detection, and Optical Coherence Tomography (OCT), use high-speed laser wavelength sweeps. There are generally two conditions that determine the lasing wavelength of a laser. The first condition, also known as the phase matching condition through the laser cavity, is that one round trip of the light through the cavity accumulates 2π·N radians, where N is an integer. Different values of N correspond to different cavity modes, which represent the possible resonant frequencies of the cavity. The second condition is that the loss through the cavity is less than the gain, or, put differently, that the transmission efficiency in the cavity is greater than zero. The range of wavelengths over which this condition is satisfied, as reflected in the wavelength-dependent transmission efficiency, can be controlled by design to limit the number of cavity modes that can exist in the cavity. The wavelength-dependent transmission efficiency thus serves as a mode-selective spectral filter. In a tunable laser as used for wavelength sweeps, the wavelength locations of the cavity modes and of the spectral filter are generally controllable independently from each other. It is desirable to maintain a certain alignment between the lasing cavity mode and the filter spectrum during the course of such tuning. Otherwise, if the selected cavity mode shifts relative to the filter, mode hopping that is, a sudden wavelength jump from one cavity mode to another—can occur. In laser wavelength sweeps, such mode hopping is generally undesirable. Accordingly, methods for aligning cavity mode and filter spectrum of a laser, to avoid or at least reduce mode hopping, are needed.

### BRIEF DESCRIPTION OF THE DRAWINGS

This disclosure provides a tunable transmission-grating laser with signed proportional feedback that facilitates aligning the cavity modes with the filter spectrum of the laser. Various embodiments are described with reference to the accompanying drawings, in which:

FIG. 1 is a schematic top view of a basic configuration of an example tunable laser with a controllable mirror and a transmission grating in accordance with various embodiments;

FIGS. 2A and 2B schematically show a spectrum of laser cavity modes and a grating filter spectrum, respectively, for the laser of FIG. 1;

FIGS. 3A and 3B show, in top views, different relative orientations between a controllable laser and a transmission grating of the laser of FIG. 1; illustrating tuning of the grating filter spectrum in accordance with various embodiments;

FIGS. 4A and 4B are schematic top views of the tunable laser of FIG. 1 illustrating ways of shifting the cavity modes of the laser without changing the filter spectrum, in accordance with various embodiments, and FIG. 4C illustrates the spectral shifting of the cavity modes in a schematic depiction of the spectrum of the cavity modes relative to the filter spectrum;

FIGS. 5A and 5B schematically show the laser cavity modes of FIG. 2A relative to the grating filter spectrum of FIG. 2B in unaligned and aligned states, respectively;

FIG. 6 is a schematic top view of an example tunable laser with a transmission grating and a mirror movable about a remote pivot point to facilitate mode-hop-free tuning, in accordance with one embodiment;

FIG. 7A is a schematic top view of the tunable laser of FIG. 1 illustrating an off-center cavity mode, as may be indirectly monitored for alignment in accordance with various embodiments, and FIG. 7B illustrates the off-center cavity mode relative to the filter spectrum of the laser;

FIG. 8 is a schematic side view of the tunable laser of FIG. 1, illustrating the tilt angle of the controllable mirror, as may be adjusted in accordance with various embodiments;

FIG. 9 is a schematic block diagram of a tunable transmission-grating laser system with feedback control, in accordance with various embodiments;

FIG. 10 is a schematic top view of a portion of the tunable transmission-grating laser system with feedback control, including the tunable laser of FIG. 1 along with a second transmission grating to create a monitoring beam, in accordance with various embodiments;

FIG. 11A is a schematic front view of a quadrant detector for measuring a monitoring beam spot, in accordance with various embodiments, and FIG. 1-1B shows, in side view, the corresponding position of the intracavity beam spot relative to the gain medium of the laser;

FIG. 12 is a schematic top view of a portion of a tunable transmission-grating laser system with feedback control that utilizes a position-sensitive diode to measure the location of the monitoring beam, in accordance with one embodiment;

FIG. 13 is a schematic top view of a portion of a tunable transmission-grating laser system with feedback control that utilizes an imaging array to measure the location of the monitoring beam, in accordance with one embodiment;

FIG. 14 is a schematic top view of a portion of a tunable transmission-grating laser system with feedback control that is configured to scan the monitoring beam across a receiver, in accordance with one embodiments;

FIG. 15A is a schematic top view of a portion of a tunable transmission-grating laser system with feedback control that is configured to measure the location of the monitoring beam with a small-area movable receiver, in accordance with one embodiment, and FIG. 15B is a front view of an example fiber-based receiver as may be used in this embodiment; and

FIG. 16 is a flowchart of a method of aligning, in a tunable laser, the intracavity beam with the gain medium, in accordance with various embodiments.

FIG. 17 is a flowchart of a method of mode-hop-free laser tuning, in accordance with various embodiments.

### DESCRIPTION

Described herein is a tunable laser that uses a controllable resonator mirror in conjunction with a mode-selective transmission grating to facilitate wavelength sweeps. Also described is an approach to aligning the selected cavity mode of the tunable laser with the grating filter spectrum of the laser, and minimizing cavity losses in the laser, by indirectly monitoring how well the laser beam inside the resonant cavity is aligned with the laser's gain medium. Movement of the intracavity beam relative to the gain medium can, in principle, provide a good feedback signal for alignment. However, it is often impractical to place detectors around the gain medium and shield them from stray light to directly measure the beam position in the laser. In accordance with various embodiments, this constraint is circumvented by creating an image of the intracavity beam, herein also referred as a “monitoring beam,” using a second transmission grating to diffract the zero-order transmission of the mode-selective transmission grating used inside the resonant cavity. The monitoring beam can be focused down to create an image of the beam spot that the intracavity beam creates on the gain medium. The displacement of that monitoring beam spot from a position associated with mode-to-filter alignment can be used as a feedback control signal to adjust the mode-selective grating and/or the controllable mirror.

The foregoing summary will be more readily understood from the following detailed description of the drawings.

FIG. 1 illustrates a basic configuration of an example tunable laser 100 in accordance with various embodiments. The laser 100 (viewed in top view, that is, in a projection onto the plane in which the beam propagates, herein also the “laser plane”) includes a resonant cavity and, inside the resonant cavity, a gain medium 102, where stimulated emission takes place. In the illustrated example, the gain medium 102 is the gain channel of a diode gain block 103. However, other types of gain media, such as doped glass (e.g., fused silica doped with erbium or ytterbium), doped crystals (YAG, titanium sapphire, ruby), gases (argon, neon, helium, fluorine), and dyes in solvents, may alternatively be used. The resonant cavity is formed between two resonator mirrors 104, 106. One of the resonator mirrors (as shown mirror 104) is controllable, and serves as the tuning element for the laser wavelength, this mirror 104 is herein also referred to as the “controllable resonator mirror” or “controllable mirror.” The other, fixed mirror 106 may be formed by the back facet of the diode gain block 103, as shown. Alternatively, a separate mirror may be placed on the side of the gain medium 102 opposite to the controllable mirror 104. Regardless of the specific implementation, the fixed mirror 106 is generally configured to couple a portion of the laser light out of the cavity and into optics that use the laser light for some purpose. Inside the cavity, a lens 108 may focus light onto the gain medium 102, and collimate the reflected light coming from the gain medium 102.

The laser 100 further includes an intracavity transmission grating 110 (herein also referred to more simply as “transmission grating 110” or simply “grating 110”), that is, a diffraction grating that transmits, rather than reflects, the diffracted light. The transmission grating 110 is placed between the controllable mirror 104 and the gain medium 102, and acts as a selective loss, or filter, that limits the wavelengths that can be present in the cavity. The controllable mirror 104 is positioned in the path of the first-order (or a higher-order) diffraction of the transmission grating 110, such that light between the grating 110 and the controllable mirror 104 propagates at an angle (e.g., approximately a right angle) with respect to light between the gain medium 102 and the grating 110.

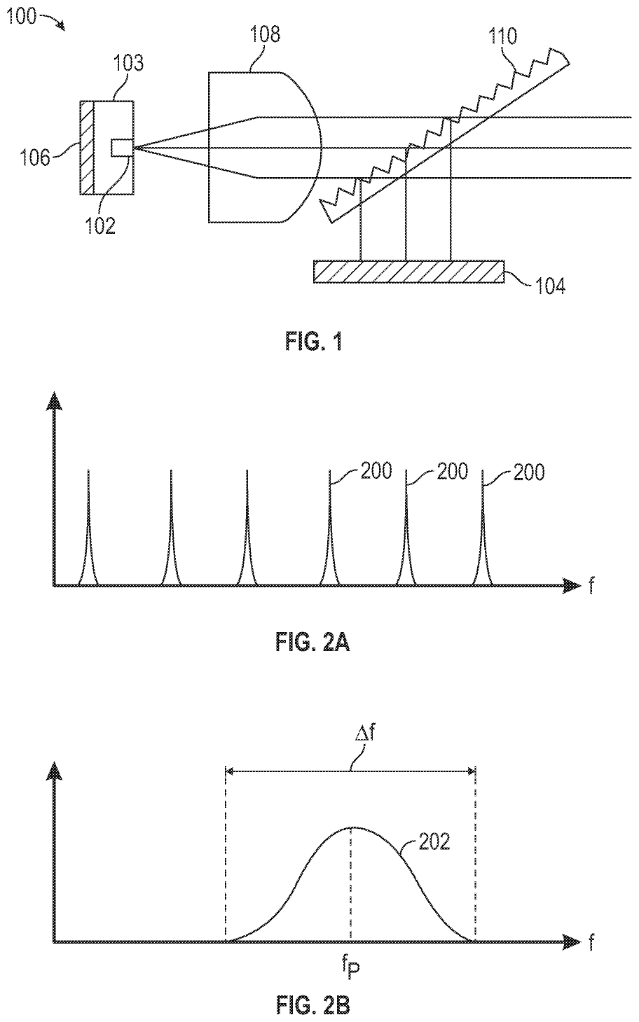

FIG. 2A schematically shows the spectrum of cavity triodes 200 of the laser 100, illustrating their even frequency spacing. The frequencies (and, thus, wavelengths) of the cavity modes 200 depend on the cavity length, which can be changed, e.g., by moving the controllable mirror 104 closer to or farther from the grating 110.

FIG. 2B schematically shows the filter spectrum 202 of the laser, which depends on the configuration of the transmission grating 110 and the mirror 104. Only cavity triodes 200 with wavelengths within the filter spectrum 202 can exist in the cavity; the transmission grating 110, thus, functions as a mode-selecting element. The spectral width Δf of the filter spectrum 202 is a function of the width of the region of the grating 110 that is illuminated by the beam in the cavity. The spectral location of the filter spectrum 202, e.g., as defined in terms of its peak frequency ƒₚ (corresponding to peak wavelength) Δₚ), depends on the angles at which the light is incident upon and diffracted from the grating 110 and the angle of the mirror 104. More specifically, the position of the peak of the filter spectrum is determined in accordance with the grating equation:

d(sin θᵢ−sin θₘ)=mλ,

where d is the periodicity of the diffraction grating (e.g., the distance between adjacent grooves in a ruled grating), θᵢ is the angle of incidence of light coming from the gain medium 102 onto the grating, θₘ is the angle of diffraction of diffraction order m (m being an integer), and λ is the wavelength. For a particular angle of incidence (θᵢ), the wavelength of the filter peak λₚ changes proportionally to the sine of the diffraction angle θₘ associated with the portion of the light in the cavity that is reflected back into the gain medium, and this angle can be controlled by the mirror 104. That is, among light diffracted at multiple angles, the resonator mirror 104 selects, by virtue of its orientation relative to the grating 110, light at one angle to be reflected back into the gain medium 102. Accordingly, the filter spectrum 202 of the laser 100 can be shifted by rotating the mirror 104 in the laser plane.

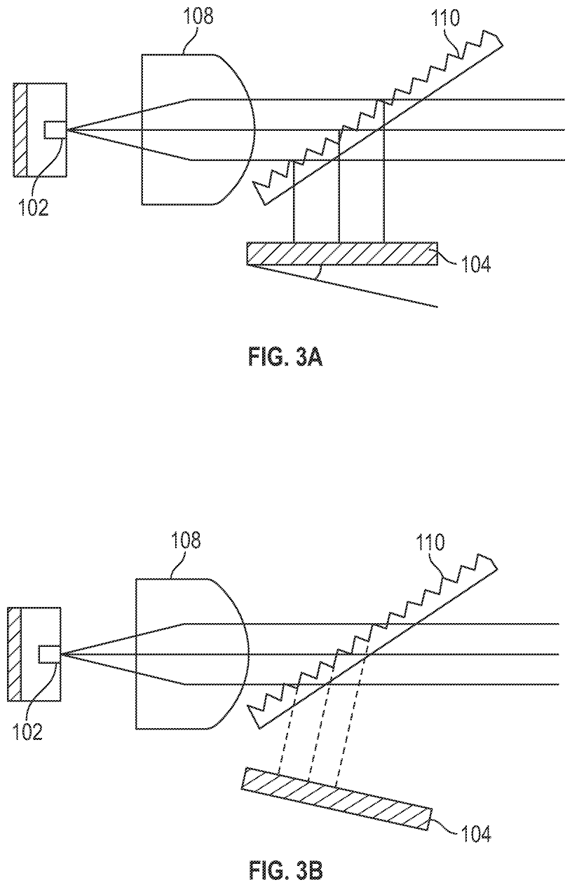

To illustrate this concept, FIGS. 3A and 3B depict, in top views, different relative orientations between the controllable mirror 104 and the transmission grating 110 of the laser 100, illustrating tuning of the filter spectrum 202 in accordance with various embodiments. The grating 110 is at a fixed position and orientation relative to the gain medium 102 (resulting in a fixed angle of incidence, θᵢ, onto the grating 110), but the controllable resonator mirror 104 is oriented at two different angles relative to the grating 110 in FIGS. 3A and 3B, respectively. The grating 110 diffracts light of different wavelengths (illustrated by solid and dashed lines, respectively) at different respective angles, and whichever wavelength is incident normally onto the mirror 104 is reflected back into the gain medium 102, and thereby enhanced in the cavity. Tilting the mirror, thus, effectively shifts the filter spectrum 202 so that its peak occurs at a different frequency ƒₚ and wavelength λₚ.

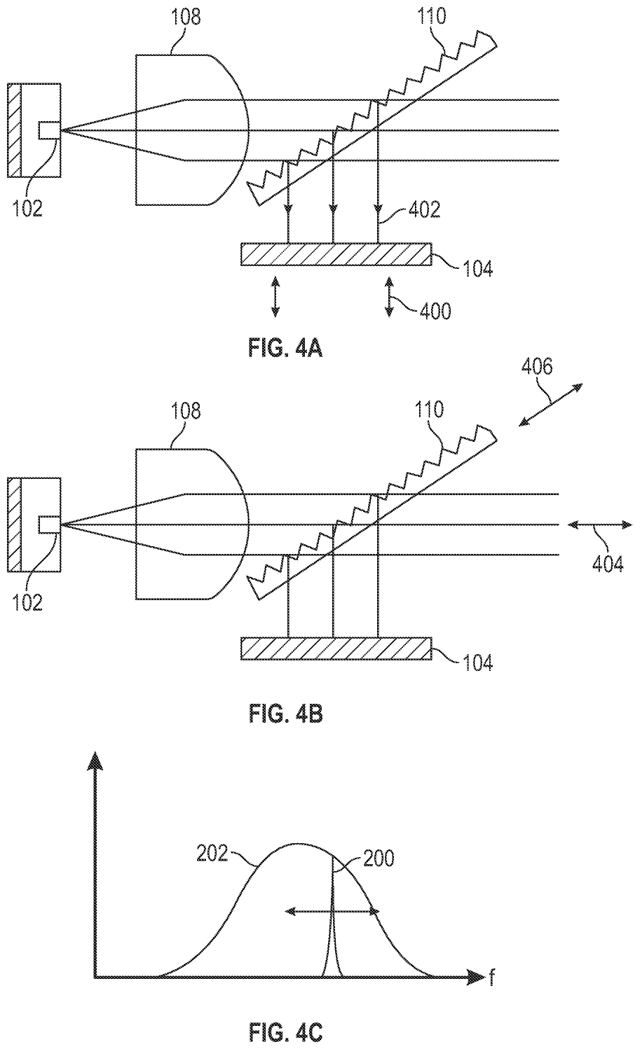

FIGS. 4A and 4B illustrate, in top views of the laser 100, various ways of shifting the cavity triodes 200 of the laser without changing the filter spectrum 202. FIG. 4C illustrates the spectral shifting of the cavity modes in a schematic depiction of the spectrum of the cavity modes 200 relative to the filter spectrum 202. The wavelength locations of the modes are determined by the following equation:

$$2 π N = \frac{2 π {L}_{opt}}{λ} + φ ,$$

where N is an integer, Lₒₚₜ is the optical length of the cavity, A is the wavelength, and φ is the sum of all of the phase shifts that occur in the cavity (such as at grating diffractions and metal reflections). Moving the mirror 104 in the general direction 400 normal to the mirror surface (which is the direction of the diffracted beam 402 that will be reflected back onto the grating 110), as shown in FIG. 4A, causes a change in the optical length of the cavity, Lₒₚₜ, specifically, the portion of the cavity between the grating 110 and the mirror 104. Alternatively, the optical length of the cavity can be changed by translating the grating 110 in a direction 404, parallel to the collimated beam that exits the lens 108, without changing the orientation of the grating, as indicated in FIG. 4B; in this case, the length of the cavity portion between the gain medium 102 and the grating 110 changes. It is also possible to translate the grating 110 in a direction 406, parallel to a plane of the grating 110, again without changing the orientation of the grating. The translating in this direction 406 does not cause a change in the cavity length, but it does cause a change in the phase shift, φ. As will be appreciated, any translation of the grating 110 in the laser plane can be described as a superposition of translations in directions 404, 406, and causes a shift in the cavity modes 200 due to some combination of a change in the optical length Lₒₚₜ and the phase shift q in the cavity.

Accordingly, changing the angle of the mirror 104 within the laser plane enables tuning the location of the filter spectrum 202, while moving the controllable mirror 104 so as to adjust the distance between the mirror 104 and the grating 110, or shifting the grating 110 to adjust the distance between the gain medium 102 and the grating 110 or the phase shift in the cavity, allows tuning the locations of the cavity modes 200, independently from the filter spectrum 202. Together, mirror angle and mirror distance to grating or grating position can be used to control the locations of the cavity modes 200 relative to the filter spectrum 202, and thereby to select a single mode that is present in the cavity, as a result of being amplified more than any other mode.

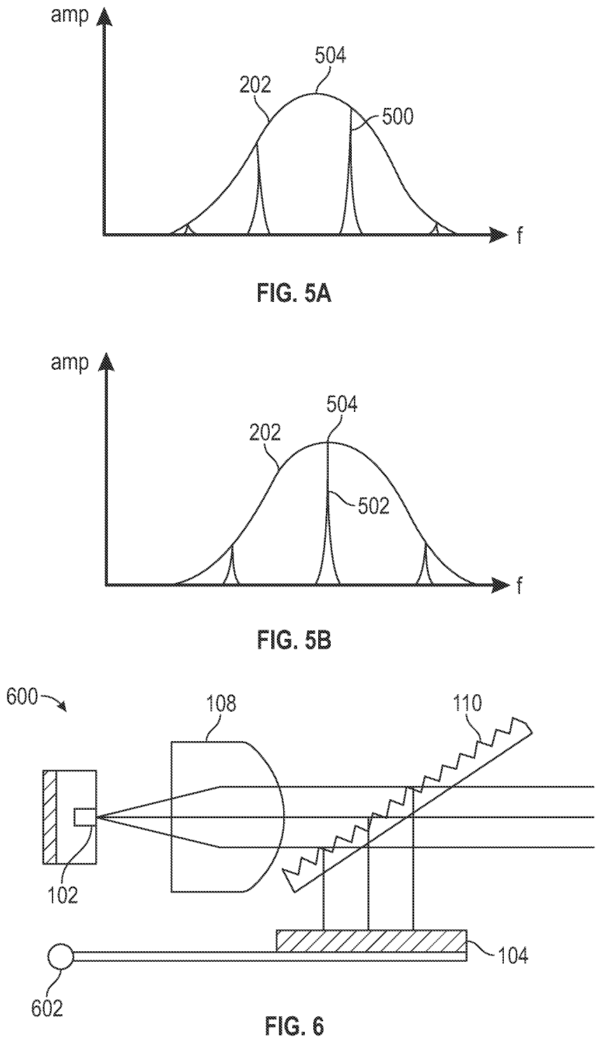

FIGS. 5A and 5B illustrate two relative positions between cavity modes 200 and filter spectrum 202, and indicate the respective selected modes 500, 502, which correspond to the modes with the highest gain. It is often desirable that the selected mode 502 is aligned with the peak 504 of the filter spectrum 202, as shown in FIG. 5B, to maximize the intensity of the laser light, although, in some cases, it may be desirable that the selected modes is aligned with a position off-set from the filter peak 504. Either way, the alignment between the selected cavity mode 502 and the filter spectrum 202 should be maintained during laser tuning. If the selected cavity mode 500 and the filter peak 504 become misaligned, e.g., if a cavity mode initially aligned with the filter peak 504 shifts away from the peak 504, as shown in FIG. 5B, not only does the beam intensity drop, but mode hopping can occur when another mode comes closer to the filter peak 504. In laser wavelength sweeps, such mode hopping is generally undesirable and should be avoided or at least reduced. Mode-hop-free laser tuning is achieved when the tuning of the selected cavity mode and of the filter spectrum are coordinated in a manner that maintains alignment between the two throughout the wavelength sweep.

FIG. 6 is a schematic top view of an example transmission-grating tunable laser 600 with a controllable mirror movable about a remote pivot point 602, illustrating one approach to achieving continuous alignment, in accordance with an embodiment. The remote pivot point 602 ties the position and angle of the mirror 104 together through a trigonometric relationship. In some instances, this may achieve mode-hop-free tuning. In other situations, the coordination between mirror position and mirror angle via the pivot point 602 does not by itself guarantee the elimination of mode hopping, but reduces any misalignment, and thus the amount of correction needed. Unfortunately, the tolerance on this pivot point 602 is often quite tight, and the trigonometric relationship may only work for a limited tuning range.

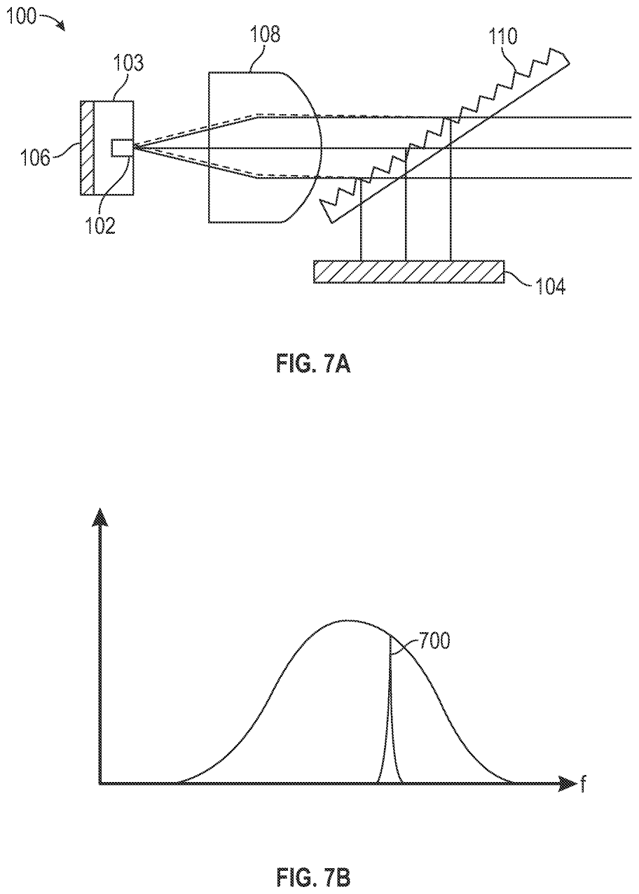

In various embodiments, spectral alignment between the cavity mode and the mode-selective filter is achieved by monitoring the spatial alignment between the intracavity laser beam and the gain medium 102. Considering again the grating equation, d(sin θᵢ−sin θₘ)=mλ, a laser cavity mode having a wavelength that does not have a diffraction angle θₘ that produces a beam that is exactly normal to the mirror constitutes an off-center mode. As shown in FIG. 7A, the intracavity beam spot of such an off-center mode 700 is spatially, displaced, in the laser plane, from the center of the gain medium 102. Further, the off-center mode 700 is spectrally displaced from the peak of the filter spectrum 202, as illustrated in FIG. 7B, due to diminished coupling into the gain medium 102. Conversely, when the lasing cavity mode is at the low-loss (maximum-diffraction) wavelength of the grating, the diffraction-limited beam spot is well-aligned with the gain medium 102 and couples back into the gain medium 102 with maximum efficiency. Accordingly, the movement of the beam spot relative to the gain medium 102 to satisfy the grating equation is a good indicator of misalignment between the cavity mode and the grating filter.

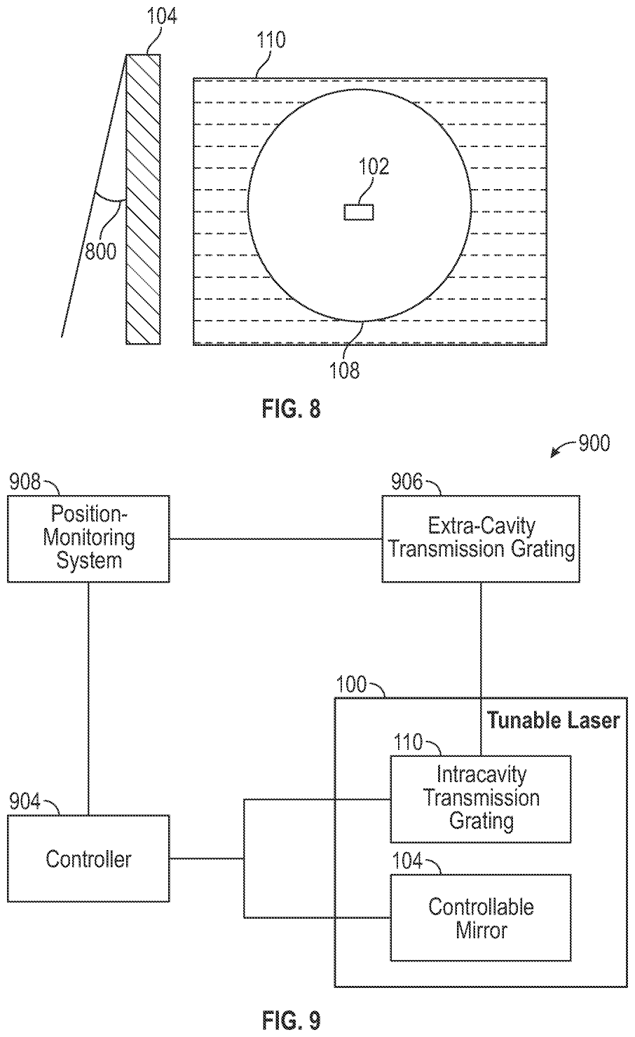

The controllable mirror 104, in addition to being rotatable and translatable in the laser plane, may have one or more additional degrees of freedom. For example, the controllable mirror 104 may have an additional degree of freedom for the tilt angle with respect to the laser plane. FIG. 8 illustrates this tilt angle 800 in a side view of the laser cavity along the collimated diffracted return beam coming from the grating 110 and focused by the lens 108 onto the gain medium 102. The tilt angle 800 is the angle of rotation about an axis defined by the intersection of the mirror plane with the laser plane. It is generally chosen so that the reflected light diffracts off the grating 110 and is focused back onto the gain medium 102. If the tilt angle 800 is off, loss is introduced into the cavity. Accordingly, it is desirable to adjust the tilt angle 800 to achieve alignment of the focused intracavity beam with the gain medium 102 also in the direction normal to the laser plane (e.g., the vertical direction if the laser plane is oriented horizontally). If the laser can be manufactured such that a low-loss angle can be maintained over time and over a range of temperatures, as well as during laser tuning, adjustments to the tilt angle can be eliminated. However, if the tilt angle 800 can be controlled, then the laser can be assembled without tight tolerances, which entails cost benefits. Such control can be achieved using the displacement of the beam spot from the gain medium 102 as a feedback signal.

FIG. 9 is a schematic block diagram of a tunable transmission-grating laser system 900 with feedback control to align the intra-cavity beam in one or two dimension (in the laser plane and/or in direction perpendicular to the laser plane), in accordance with various embodiments. The system 900 includes a tunable laser 100 as described with reference to FIG. 1, with a transmission grating 110 inside the resonant cavity, used for mode selection, and with a controllable resonator mirror 104. The controllable mirror 104 and/or the transmission grating 110 are movable along various degrees of freedom, for instance, by suitable electronically driven actuators, such as translation stages, pistons, electrostatically controlled microelectromechanical systems (MEMS) actuators, voice coil actuators, and/or set screws, as known to those of ordinary skill in the art. In some embodiments, the controllable mirror 104 can be moved linearly in the laser plane generally away from or towards the transmission grating 110, as well as be rotated within the laser plane and tilted relative to the laser plane (as described with reference to 3A-4B). The transmission grating 110 itself may likewise be movable linearly in the laser plane (as illustrated with reference to FIG. 4B).

A controller 904 can control these degrees of freedom for the motion of the mirror 104 and transmission grating 110 to tune the wavelength of the tunable laser 100 while aligning the laser beam with the gain medium. The controller may be implemented by any suitable combination of hardware and/or software. For example, in some embodiments, the controller is implemented by a digital signal processor (DSP), application-specific integrated circuit (ASIC), field-programmable gate array (FPGA), or other electronic circuitry. In other embodiments, the controller is implemented in software running on a general-purpose computer, that is, with processor-executable instructions stored in memory and executed by one or more hardware processors of the computer. The instructions may also be stored separately on any machine-readable medium, that is, any medium that is capable of storing, encoding, or carrying instructions for execution by a computing machine, along with any data structures used by or associated with such instructions. Non-limiting machine-readable medium examples include solid-state memories, and optical and magnetic media. Specific examples of machine-readable media include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); Solid State Drives (SSD); and CD-ROM and DVD-ROM disks. In some examples, the machine-readable media include non-transitory machine readable media.

The system 900 further includes a second transmission grating 906 outside the resonant cavity (hereinafter also referred to as the “extra-cavity transmission grating” 906) that refracts the zero-order transmission of the intracavity transmission grating 110 to generate a monitoring beam, and a position-monitoring subsystem 908 to measure the movement of a monitoring beam spot and its displacement from a position that corresponds to intracavity-beam alignment with the gain medium. As noted, the creation of such a monitoring beam and beam spot serves to get around spatial constraints inside the cavity that would make detector placement near the gain medium 102 impractical if not impossible. The measured position or displacement of the monitoring beam spot is provided as a feedback signal to the controller 904, which can then adjust resonator mirror 104 and transmission grating 110 accordingly.

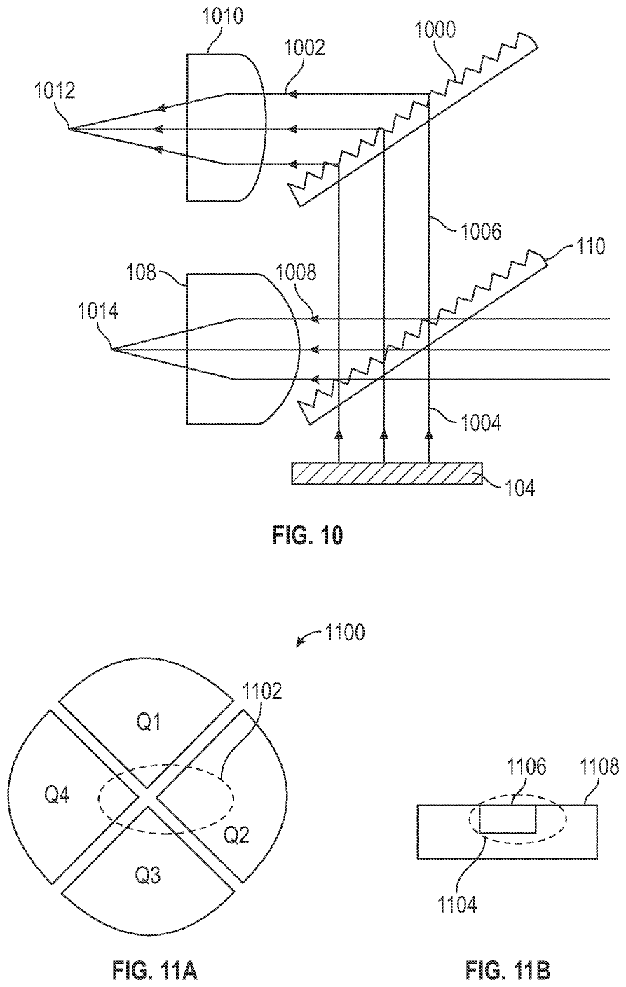

FIG. 10 is a schematic top view of the tunable laser 100 along with a second, extra-cavity transmission grating 1000 (corresponding to grating 906) to create a monitoring beam 1002, in accordance with various embodiments, that allows indirectly measuring the displacement of the intracavity laser beam from the gain medium 102. The second transmission grating 1000 is placed outside the resonant cavity, in the path of the zero-order transmission (through the transmission grating 110, disposed intracavity) of the return beam 1004 coming from the controllable mirror 104; this zero-order transmission is herein also referred to as the “zero-order return beam” 1006, whereas the diffraction of the return beam 1004 back into the gain medium 102 is referred to as the “refracted return beam.”

The second transmission grating 1000 is oriented parallel to the transmission grating 110, or more generally, at an angle relative to the path of the zero-order return beam 1006 equal to an angle of the transmission grating 110 relative to the return beam 1004 (to allow for redirection of the zero-order return beam 1006 before it encounters the second transmission grating 1000). With this orientation of the second transmission grating 1000, the produced monitoring beam 1002 will be an image of the diffracted return beam 1008. The monitoring beam 1002 can be focused, e.g., by a lens 1010 or other focusing optic, to a monitoring beam spot 1012 that is an image of the beam spot 1014 on the gain medium 102 inside the resonant cavity. If that lens 1010 has the same focal length as the lens 108, the monitoring spot 1012 will be substantially identical to the beam spot 1014. There are advantages, however, to focusing the monitoring beam 1002 through a lens with longer focal length, as this will make the monitoring beam spot 1012 bigger and the spatial deflection from its alignment position larger. It is also possible to have no lens at all and simply place the position sensor in the far field of the beam, but this is generally impractical because of the large propagation distances needed. The position of the monitoring beam spot 1012 can be measured in various ways, as illustrated below with reference to FIGS. 11A-15B. Detectors and other means for measuring the beam spot, along with the focusing lens 1010, constitute the position-monitoring subsystem 908.

In some embodiments, the monitoring beam spot s measured with a position-sensitive detector placed at the focal plane of the lens 1010. As one example of a position-sensitive detector, FIG. 11A shows, in front view, a quadrant detector 1100, along with the position of the monitoring beam spot 1102 relative to the detector 1100. For comparison, FIG. 11B shows, in side view, the position of the intracavity beam spot 1104 relative to the gain channel 1106 of a diode gain block 1108, which may serve as the gain medium 102 in one embodiment. As can be seen, the intracavity beam spot 1104 is slightly displaced from the center of the gain channel 1106. If the quadrant detector 1100 is positioned, e.g., based on a calibration process preceding a measurement, such that, for an aligned intracavity laser beam, the monitoring beam spot would be centered on the detector 1100, the misalignment shown in FIG. 11B will be reflected by an off-center position of the monitoring beam spot 1102 on the detector, as shown in FIG. 1.1A.

The amount of misalignment can be quantified by measuring the difference in the amount of detected light (as will translate into a difference in photocurrents) between opposing quadrants of the detector 1100. A misalignment in the laser plane (as shown), corresponding to a cavity mode that does not coincide with the filter spectrum peak, will result in a non-zero photocurrent difference between quadrants Q2 and Q4. A vertical, out-of-plane misalignment, as results when the tilt angle of the controllable mirror 104 relative to the laser plane is off, would result in a non-zero photocurrent difference between quadrants Q1 and Q3. Beneficially, a quadrant detector, e.g., made of indium gallium arsenide (InGaAs) or germanium (Ge), can be used at laser operating wavelengths in the near infrared regime, e.g., at 1550 nm, which is outside the detection band of silicon-based detectors. In addition, the four detectors that make up the quadrant detector 1100 are affordable, and require only a few extra acquisition channels, but have no moving parts.

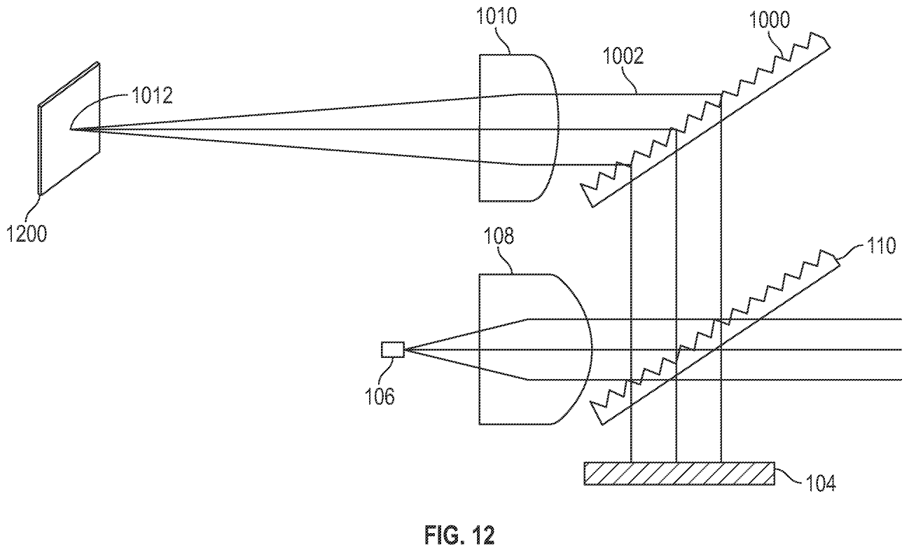

FIG. 12 shows, in a schematic top view, a portion of a tunable laser system that utilizes, as an alternative to a quadrant detector 1100, a position-sensitive diode (PSD) 1200 at the focal plane of the lens 1010 to measure the location of the monitoring beam spot 1012, in accordance with one embodiment. PSDs provide continuous position information based on local resistance changes measured with electrodes connected to the device at various locations,

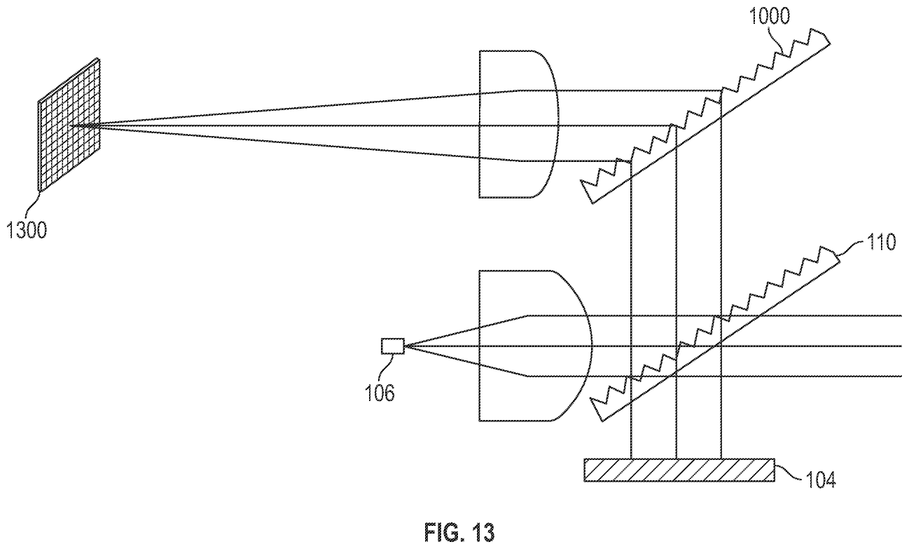

FIG. 13 illustrates, again in schematic top view, yet another embodiment, in which an imaging array 1300 is used to measure the position of the beam spot 1012, Unlike a PSD, the imaging array 1300 provides discrete position information in its pixelated image. The imaging array 1300 may be, for instance, a charge-coupled device whose sensor pixels are implemented by complementary metal oxide semiconductor (CMOS) capacitors. Depending on the operating wavelength range of the tunable laser, a CMOS-based imaging array may or may not be cost-effective. For example, a CMOS-based imaging array that can detect light at wavelengths around 1550 nm, as are often used in OFDR systems, can cost more than $10,000, However, for wavelengths shorter than 1000 nm, silicon-based CMOS imaging arrays, which may be as cheap as about $1, can be used. Accordingly, for short wavelengths, CMOS imaging arrays are a suitable option for a position-sensitive detector to measure the monitoring beam spot.

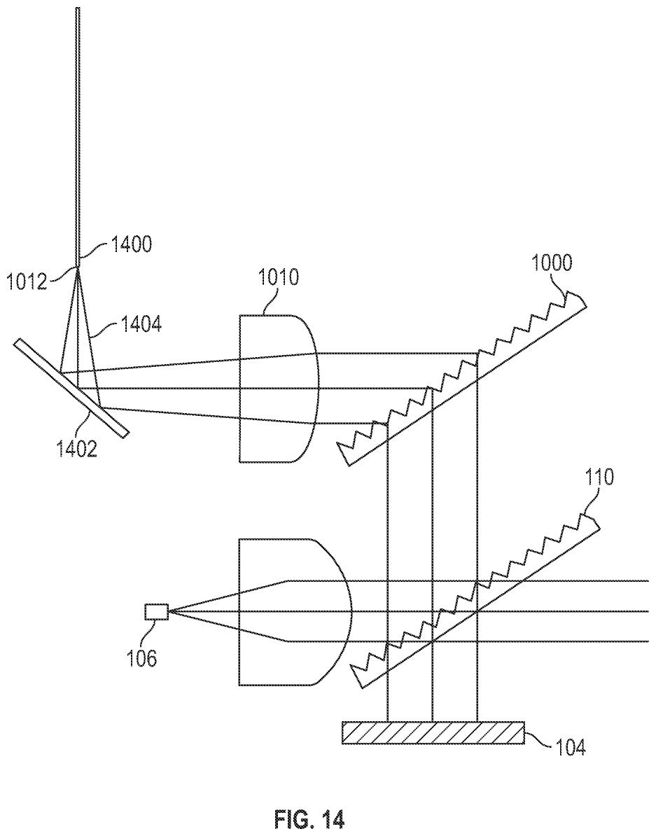

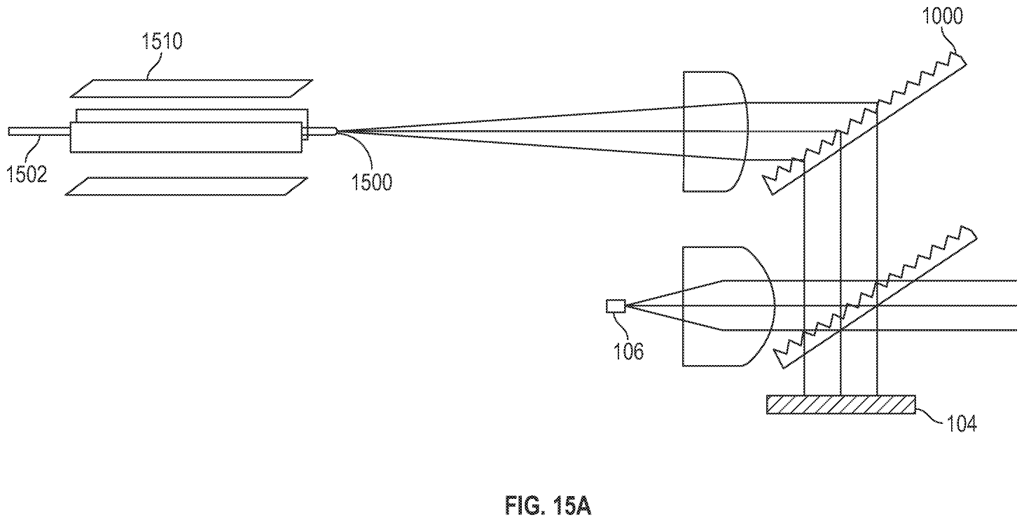

FIG. 14 illustrates, in a schematic top view, a portion of a tunable laser system in which the location of the focused monitoring beam spot 1012 is determined, in accordance with various embodiments, using a single, small area receiver in conjunction with a scanning mirror 1402 (or other beam scanner) in the path between the focusing lens 1010 and the receiver 1400 that scans the focused monitoring beam 1404 across the receiver 1400. In this position-monitoring system, the receiver 1400 is kept at a fixed location, and the scanning mirror 1402 is moved linearly, e.g., towards or away from the focusing lens 1010, or rotated on the laser plane, to move the monitoring beam spot 1012. The receiver 1400 may, for instance, be an individual photodetector, or as shown, the input face of an optical fiber coupled, at the other end, to a photodetector.

The mirror position and/or orientation can be calibrated by aligning the intracavity beam with the gain medium, and then translating or rotating the mirror 1402 to scan the focused monitoring beam 1404 across an area including the receiver 1400, and determining the position and/or orientation of the mirror 1402 in the laser plane at which the focused monitoring beam 1404 is detected at the receiver 1400 and the measured intensity is maximized. When the laser is subsequently misaligned, the monitoring beam spot 1012 will generally no longer coincide with the receiver 1400. The misalignment of the laser can then be quantified by determining the distance by which the mirror 1042 needs to be moved, or the angle by which it needs to be rotated, relative to the calibrated position or orientation, to redirect the focused monitoring beam 1404 onto the receiver 1400. It is also possible, alternatively, to use the position-monitoring system of FIG. 12 in a manner similar to the quadrant detector of FIG. 11A, by moving the mirror 1402 to four (or more) different predetermined linear positions or orientations, and measuring the detected intensity at the receiver 1400. The mirror motions are, in this case, chosen sufficiently small to keep the monitoring beam spot 1012 overlapping with the receiver 1400, allowing the receiver 1400 to measure the intensity at different locations within the monitoring beam spot 1012. Using a scanning mirror 1402 to measure the monitoring beam has the benefit that only a single detection channel is needed, which, however, comes at the cost of moving parts and usually multiple sweeps.

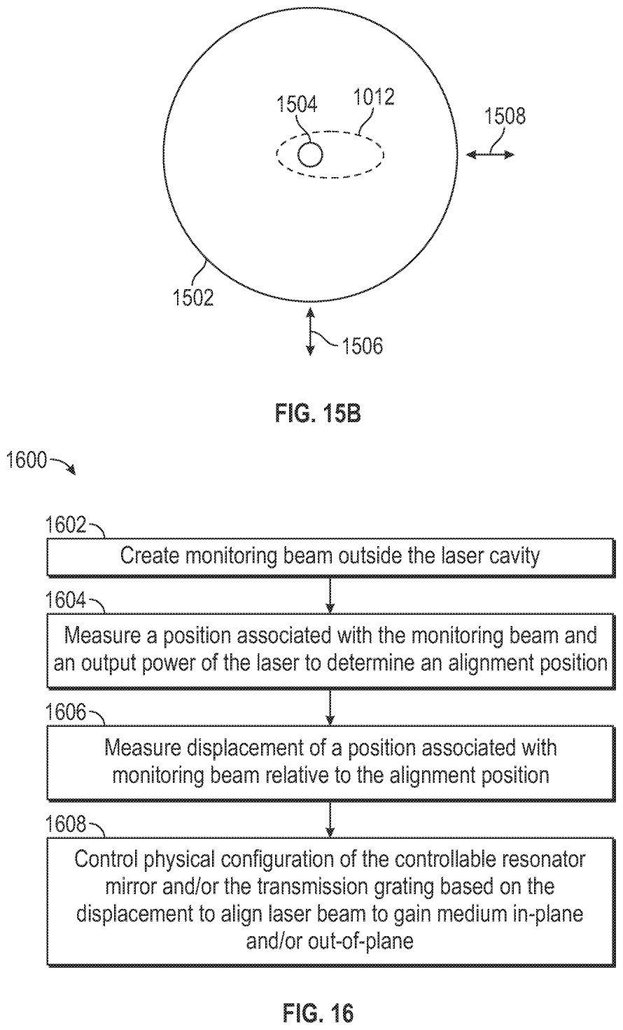

FIG. 15A illustrates, in a schematic top view, of a portion of a tunable laser system that likewise uses a small-area receiver 1500, but moves the receiver itself, rather than the monitoring beam as in FIG. 14. Here, too, the receiver 1500 may be, for example, an individual photodetector, or the input face of an optical fiber 1502 (as shown) coupled, at the other end, to a photodetector. FIG. 1513 is a front view of an example fiber-based receiver as may be used in this embodiment, illustrating the relative sizes of the monitoring beam spot 1012, the fiber 1502, and the fiber core 1504. In one example, the fiber is a 125 μm standard optical fiber with a 9 μm fiber core. The input face of the fiber 1502 may be moved, e.g., by up to 100 μm in both directions, both vertically (1506) and horizontally (1508). Fiber movement may be accomplished, for instance, using electrostatic fields generated between pairs of capacitor plates 1510, or by magnetic or piezoelectric means.

FIG. 16 is a flowchart of a method 1600 of aligning, in a tunable laser 100, the intracavity beam with the gain medium, in accordance with various embodiments. The method 1600 involves creating a monitoring beam outside the laser cavity by diffracting a zero-order return beam transmitted through the intracavity grating off a second, extra-cavity transmission grating (1602). The monitoring beam serves as an image of the intracavity beam, and its focused beam spot, or some other position associated with the monitoring beam, can be used to determine whether the intracavity beam is aligned. For this purpose, the alignment position of the monitoring beam spot, that is, the position of the beam spot when the intracavity beam is aligned with the gain medium (in the laser plane by virtue of the alignment of the lasing cavity mode with the laser's filter peak, or in a direction perpendicular to the laser plane) is determined, e.g., in a calibration step (1604).

Calibration (at 1604) may be performed by scanning the controllable resonator mirror 104 of the tunable laser over a range of angles and linear positions while the output power of the laser and the monitoring spot position are monitored. From this data, a map of the spot position versus laser output power can be generated. The alignment position of the monitoring spot is generally the position at which the laser output power is maximized. Instead of measuring and recording the position of the monitoring beam spot itself, it is also possible to monitor a position otherwise associated with the monitoring beam spot, such as the angular position other words, orientation) of a scanning mirror when the mirror redirects the monitoring beam onto a fixed receiver, as illustrated in FIG. 14. The alignment position of the scanning mirror is the angular position at which the mirror directs the monitoring beam onto the receiver when the intracavity beam is aligned with the gain medium. The calibration may be performed, e.g., upon start-up of the laser, and thereafter as needed, e.g., to compensate for laser drift over time and/or temperature.

Following calibration, the displacement of the beam spot, or other position associated with the monitoring beam, from the alignment position can be measured (1606) and used as feedback to control the physical configuration of the controllable resonator mirror 104, the transmission grating 110, or both (1608). Control parameters of the configuration include, for example, the position of the controllable mirror along the direction of the return beam and the position of the transmission grating 110 in the laser plane, both of which affect the cavity modes, as well as the tilt angle of the controllable mirror 104, which determines the out-of-plane alignment of the focused intracavity beam with the Gain medium 102.

Adjustments to the control parameters may in principle be made in real-time as the laser is being tuned, e.g., using a control signal output by a proportional-integral-derivative (PID) controller. In many systems and applications, however, the laser sweep rate is too high for real-time adjustments to be feasible. For example, if a CMOS or similar imaging array is used in the position-monitoring subsystem, the read-out rate from the array may be significantly lower than the sweep rate. However, swept lasers often operate in a quasi-steady state, where the drive signals to the controllable mirror 104 and/or a gain diode providing the gain medium are repetitive and generally occur at above 100 Hz. In such systems, it is possible to characterize the sweep, in terms of the monitoring beam position as a function of drive signal or wavelength, over the course of multiple sweeps, and then make adjustments at a rate lower than sweep rate. With an imaging array determining the position of the beam monitoring spot, for example, a fast global shutter may be used to expose the array during each sweep for only a brief slice of the total sweep, and this slice is then advanced relatively slowly through the sweep. If a sweep takes, for instance, 3 ms, and the exposed slice covers 5 is, then after six hundred samples, the full sweep is characterized. If, further, the imaging array can be read at thirty frames per second, it will take twenty seconds to fully characterize the sweep. In practice, the spot may be very localized, such that it suffices to read out a much smaller set of pixels. This region-of-interest (ROI) read-out of an imaging array is very common for CMOS devices, and may allow effective frame rates above, e.g., 600 Hz, corresponding to an update rate of about 1 Hz.

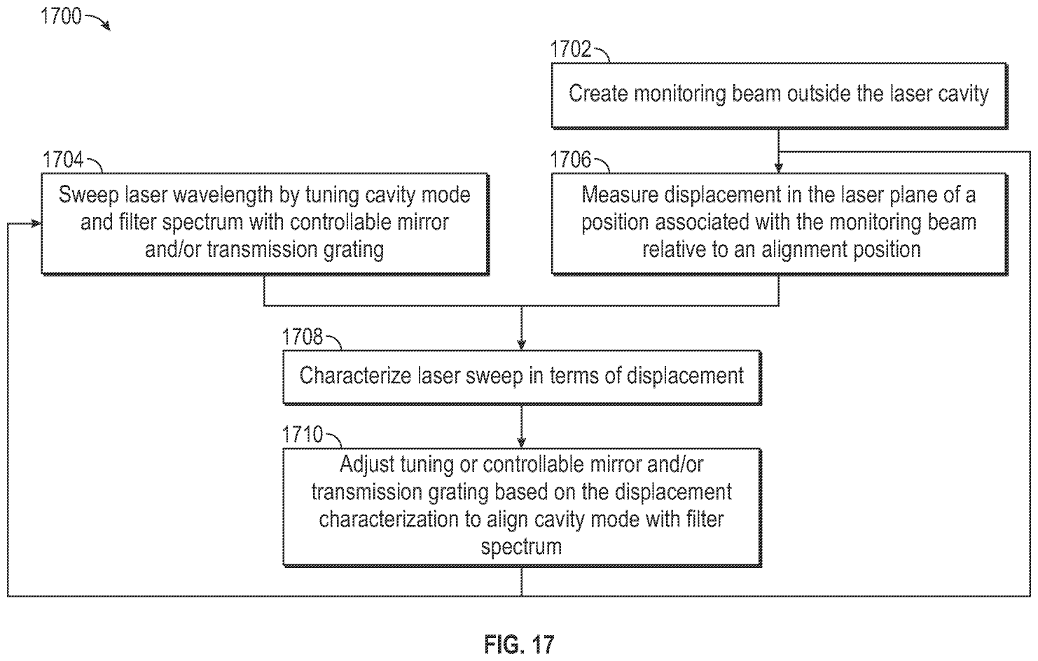

FIG. 17 is a flowchart of a method 1700 of mode-hop-free laser tuning, in accordance with various embodiments, as an example application of the general alignment method of FIG. 16. The mode-hop-free tuning method 1700 includes creating a monitoring beam outside the laser cavity (1702) and, as the laser wavelength is swept (1704), measuring the displacement, in the laser plane, of a position associated with the monitoring beam relative to its alignment position (1706). Performing the laser sweep (1704) involves simultaneously tuning the cavity mode and the filter spectrum of the laser, using the linear position of the controllable mirror 104 or the grating 110 to tune the mode and the rotational angle of the controllable mirror 104 to tune the filter. If the mode and filter spectrum do not remain aligned throughout the sweep, a non-zero displacement will be measured (in 1706). The displacement measurements across the wavelength tuning range may be measured over multiple sweeps, and are then assembled into a curve characterizing the laser sweep in its entirety (1708). This characterization is used, by controller 904, to adjust the drive forms for tuning the controllable mirror 104 and/or the transmission grating 110, to better align the cavity mode with the filter spectrum (1710). The characterization and adjustment process can be repeated throughout subsequent sweeps.

Although the various aspects of the present invention have been described with respect to a preferred embodiment, it will be understood that the invention is entitled to full protection within the fll scope of the appended claims.

1. In a tunable laser system comprising a mode-selective first transmission grating disposed in a resonant cavity between a gain medium and a controllable resonator mirror, a method for aligning a diffracted return beam with the gain medium, the diffracted return beam resulting from diffraction of a return beam from the controllable resonator mirror off the first transmission grating, the method comprising:
creating a monitoring beam outside the resonant cavity by diffracting, off a second transmission grating disposed outside the resonant cavity, a zero-order return beam transmitted through the first transmission grating;
measuring a displacement of a position associated with the monitoring beam relative to an alignment position; and
controlling a physical configuration based on the measured displacement, the physical configuration being of the controllable resonator mirror, or of the first transmission grating, or of both the controllable resonator mirror and the first transmission grating.

2. The method of claim 1, wherein the physical configuration comprises at least one parameter selected from the group consisting of: a position of the controllable resonator mirror along a direction of the return beam, a position of the first transmission grating in a laser plane defined by the return beam and the diffracted return beam, and a tilt angle of the controllable resonator mirror with respect to the laser plane.

3. The method of claim 2, wherein:
measuring the displacement comprises: measuring a displacement in the laser plane of the position associated with the monitoring beam relative to the alignment position; and
controlling the physical configuration comprises: controlling the position of the controllable mirror along the direction of the return beam or the position of the first transmission grating in the laser plane to align a cavity mode of a laser of the tunable laser system with a filter spectrum associated with the first transmission grating and the controllable resonator mirror.

4. The method of claim 2, wherein:
measuring the displacement comprises: measuring a displacement out of the laser plane of the position associated with the monitoring beam from the alignment position; and
controlling the physical configuration comprises: controlling the tilt angle of the resonator mirror based on the measured displacement out of the laser plane to align the diffracted return beam with the gain medium in a direction normal to the laser plane.

5. (canceled)

6. The method of claim 2, further comprising:
calibrating the tunable laser system by measuring the position associated with the monitoring beam and an output power of a laser of the laser system over a range of positions and over a range of tilt angles of the resonator mirror to create a mapping between the position associated with the monitoring beam and the output power, the range of positions being of the controllable resonator mirror along the direction of the return beam or of the first transmission grating in the laser plane; and
determining the alignment position based on the mapping.

7. The method of claim 1, further comprising:
focusing the monitoring beam onto a position-sensitive detector, wherein the position associated with the monitoring beam is a position of the focused monitoring beam on the position-sensitive detector; or
focusing the monitoring beam and using a scanning mirror to scan the focused monitoring beam across an area containing a small-area receiver, wherein the position associated with the monitoring beam corresponds to an orientation of the scanning mirror when the focused monitoring beam is incident on the small-area receiver; or
focusing the monitoring beam and scanning the small-area receiver across an area intersected by the focused monitoring beam, wherein the position associated with the monitoring beam corresponds to a position of the small-area receiver within the scanned area when the focused monitoring beam is incident on the small-area receiver.

8-9. (canceled)

10. A tunable laser system comprising:
a first resonator mirror and a second resonator mirror, the first and second resonator mirrors forming a resonant cavity, the first resonator mirror being controllable;
a gain medium disposed inside the resonant cavity;
a mode-selecting first transmission grating disposed inside the resonant cavity between the gain medium and the controllable resonator mirror, the first transmission grating configured to generate, from a return beam received from the controllable resonator mirror, a diffracted return beam and a zero-order return beam;
a second transmission grating disposed outside the resonant cavity in a path of the zero-order return beam, the second transmission grating configured to diffract the zero-order return beam to generate a monitoring beam;
a position monitoring subsystem configured to measure a displacement of a position associated with the monitoring beam relative to an alignment position; and
a controller configured to control a physical configuration based on the measured displacement, the physical configuration being of the controllable resonator mirror, or of the first transmission grating, or of both the controllable resonator mirror and the first transmission grating.

11. The tunable laser system of claim 10, wherein the physical configuration comprises at least one parameter selected from the group consisting of: a position of the controllable resonator mirror along a direction of the return beam, a position of the first transmission grating in a laser plane defined by the return beam and the diffracted return beam, and a tilt angle of the controllable resonator mirror with respect to the laser plane.

12. The tunable laser system of claim 11, wherein
the position monitoring subsystem is configured to measure the displacement by: measuring a displacement in the laser plane of the position associated with the monitoring beam relative to the alignment position; and
the controller is configured to control the physical configuration by: controlling the position of the controllable mirror along the direction of the return beam or the position of the first transmission grating in the laser plane to align a cavity mode of a laser of the tunable laser system with a filter spectrum associated with the first transmission grating and the controllable resonator mirror.

13. The tunable laser system of claim 11, wherein:
the controller is further configured to: tune a wavelength position of a filter spectrum associated with the first transmission grating and the controllable resonator mirror by adjusting an orientation of the controllable resonator mirror in the laser plane;
the position monitoring subsystem is configured to measure the displacement in the laser plane by: measuring the displacement in the laser plane across a tuning range of the wavelength position of the filter spectrum; and
the controller is further configured to control, while the filter spectrum is being tuned, the position of the controllable resonator mirror along the direction of the return beam or the position of the first transmission grating in the laser plane based on the displacement in the laser plane measured, for an instantaneous wavelength position of the filter spectrum, to achieve mode-hop-free wavelength tuning.

14. (canceled)

15. The tunable laser system of claim 13, wherein:
the position monitoring subsystem is configured to measure the displacement in the laser plane while the filter spectrum is being tuned; and
the controller is configured to control the position of the controllable resonator mirror by: controlling in a feedback control loop.

16. The tunable laser system of claim 11, wherein:
the position monitoring subsystem is configured to measure the displacement by: measuring a displacement out of the laser plane of the position associated with the monitoring beam from the alignment position; and
the controller is configured to control the physical configuration by: controlling the tilt angle of the resonator mirror based on the measured displacement out of the laser plane to align the diffracted return beam with the gain medium in a direction normal to the laser plane.

17. The tunable laser system of claim 11, wherein:
the position monitoring subsystem is configured to measure the displacement by: measuring the displacement both in the laser plane and out of the laser plane; and
the controller is configured to control the physical configuration by: controlling the position of the controllable resonator mirror relative along the direction of the return beam or the position of the first transmission grating in the laser plane, and controlling the tilt angle of the controllable mirror.

18. The tunable laser system of claim 11, wherein the controller is further configured to:
create, based on the position associated with the monitoring beam and an output power of a laser of the laser system over a range of positions and over a range of tilt angles of the resonator mirror, a mapping between the position associated with the monitoring beam and the output power, the range of positions being of the controllable resonator mirror along the direction of the return beam or of the first transmission grating in the laser plane; and
determine the alignment position based on the mapping.

19. The tunable laser system of claim 10, further comprising:
a first focusing optic, disposed inside the resonant cavity, to focus the diffracted return beam onto the gain medium; and
a second focusing optic, disposed outside the resonant cavity, to focus the monitoring beam.

20. The tunable laser system of claim 19, wherein a focal length of the second focusing optic is greater than a focal length of the first focusing optic.

21. The tunable laser system of claim 10, wherein the position monitoring subsystem comprises a position-sensitive detector disposed in a path of the monitoring beam, and wherein the position associated with the monitoring beam corresponds to a position of the monitoring beam on the position-sensitive detector.

22. (canceled)

23. The tunable laser system of claim 10, wherein the position monitoring subsystem comprises a small-area receiver and a beam scanner, the beam scanner configured to scan the monitoring beam across an area containing the small-area receiver, wherein the position associated with the monitoring beam corresponds to an orientation of the beam scanner when the monitoring beam is incident on the small-area receiver.

24. The tunable laser system of claim 10, wherein the position monitoring subsystem comprises a movable small-area receiver and an actuation mechanism configured to move the small-area receiver across an area intersected by the monitoring beam, wherein the position associated with the monitoring beam corresponds to a position of the small-area receiver when the monitoring beam is incident on the small-area receiver.

25. The tunable laser system of claim 10, wherein the position monitoring subsystem comprises a small-area receiver configured to receive incident light from the monitoring beam, the small-area receiver comprising a photodetector, or an input face of an optical fiber coupled to a photodetector at an output end of the optical fiber.

26-30. (canceled)

31. A machine-readable medium comprising a plurality of machine-readable instructions which when executed by one or more processors associated with a tunable laser system comprising a mode-selective first transmission grating disposed in a resonant cavity between a gain medium and a controllable resonator mirror, cause the one or more processors to perform a method comprising:
creating a monitoring beam outside the resonant cavity by diffracting, off a second transmission grating disposed outside the resonant cavity, a zero-order return beam transmitted through the first transmission grating;
measuring a displacement of a position associated with the monitoring beam relative to an alignment position; and
controlling a physical configuration based on the measured displacement, the physical configuration being of the controllable resonator mirror, or of the first transmission grating, or of both the controllable resonator mirror and the first transmission grating.

32. The machine-readable medium of claim 31, wherein:
the controllable resonator mirror has a position along a direction of the return beam;
the first transmission grating has a position of in a laser plane defined by the return beam and the diffracted return beam;
measuring the displacement comprises: measuring a displacement in a laser plane of the position associated with the monitoring beam relative to the alignment position; and
controlling the physical configuration comprises: controlling the position of the controllable mirror along a direction of the return beam or the position of the first transmission grating in the laser plane to align a cavity mode of a laser of the tunable laser system with a filter spectrum associated with the first transmission grating and the controllable resonator mirror.

33. The machine-readable medium of claim 31, wherein:
a laser plane is defined by the return beam and the diffracted return beam;
the controllable resonator mirror has a tilt angle with respect to the laser plane;
measuring the displacement comprises: measuring a displacement out of a laser plane of the position associated with the monitoring beam from the alignment position; and
controlling the physical configuration comprises: controlling a tilt angle based on the measured displacement out of the laser plane to align the diffracted return beam with the gain medium in a direction normal to the laser plane, the tilt angle being of the controllable resonator mirror with respect to the laser plane.

34. The tunable laser system of claim 10, wherein the second transmission grating is oriented at an angle relative to a path of the zero-order return beam equal to an angle of the first transmission grating relative to a path of the return beam.
